(19) United States
(12) Patent Application Publication
(10) Pub. No.: US 2023/0402481 A1
(43) Pub. Date: Dec. 14, 2023

(54) SEMICONDUCTOR STRUCTURE AND METHOD FOR FORMING SAME

(71) Applicants: Semiconductor Manufacturing International (Beijing) Corporation, Beijing (CN); Semiconductor Manufacturing International (Shanghai) Corporation, Shanghai (CN)

(72) Inventors: Bingquan WANG, Beijing (CN); Siriguleng ZHANG, Beijing (CN); Dayong YAN, Beijing (CN); Zhigao WANG, Beijing (CN); Hui REN, Beijing (CN)

(73) Assignees: Semiconductor Manufacturing International (Beijing) Corporation, Beijing (CN); Semiconductor Manufacturing International (Shanghai) Corporation, Shanghai (CN)

(21) Appl. No.: 18/202,430

(22) Filed: May 26, 2023

(30) Foreign Application Priority Data
Jun. 9, 2022 (CN) 202210648371.5

(51) Int. Cl. H01L 27/146

(52) U.S. Cl. CPC H01L 27/14632; H01L 27/14636; H01L 27/14687

(57) ABSTRACT

The present disclosure relates to a semiconductor structure and a method for forming the semiconductor structure. The semiconductor structure includes: a first wafer, including a first substrate and a first dielectric layer on the first substrate, a plurality of through-silicon via (TSV) structures in an array arrangement are formed in the first substrate, and the TSV structures extend through the first substrate along a direction from the first substrate to the first dielectric layer and extend into a partial thickness of the first dielectric layer; and an isolation ring structure, arranged in the first substrate around the plurality of TSV structures and extending through the first substrate along the direction from the first substrate to the first dielectric layer.

### CROSS REFERENCE TO RELATED APPLICATIONS

This application is based on and claims priority to Chinese patent Application No. 202210648371.5, filed Jun. 9, 2022, the entire content of which is incorporated herein by reference.

### TECHNICAL FIELD

The present disclosure relates to the technical field of semiconductor manufacturing, and in particular, to a semiconductor structure and a method for forming the same.

### BACKGROUND

An image sensor is generally classified into two categories: a charge coupled device (CCD) image sensor and a complementary metal oxide semiconductor image sensor (CMOS Image Sensor, CIS) depending on different operating principles and physical structures. The CMOS image sensor has the characteristics such as low power consumption, low costs, and compatibility with the CMOS process, and therefore increasingly more widely used.

In a current manufacturing process, a chip stacking technology is usually used, such as a 3D chip stacking technology. An image sensor module is fabricated in a chip, a signal processing module is fabricated in another chip, and then chips are stacked together by bonding between wafers to form the image sensor. In addition, in order to avoid blocking of light entering a photosensitive semiconductor by a metal interconnecting layer and improve utilization efficiency of light by a pixel unit, a back side illuminated (BSI) CMOS image sensor is formed by using the BSI process. Specifically, the BSI CMOS image sensor transfers a circuit part originally between a lens and the photosensitive semiconductor to a position around or under the photosensitive semiconductor, so that the light may directly enter the photosensitive semiconductor. Therefore, the blocking of the light entering the photosensitive semiconductor by the metal interconnecting layer can be avoided, and the utilization efficiency of light by the pixel unit can be improved.

### SUMMARY

The present disclosure relates to a semiconductor structure and a method for forming the same, so as to improve performance of the formed semiconductor structure.

In an aspect of the present disclosure, a semiconductor structure is provided. The semiconductor structure may include:
a first wafer, including a first substrate and a first dielectric layer on the first substrate, where a plurality of through-silicon via (TSV) structures in an array arrangement are formed in the first substrate, and the TSV structures extend through the first substrate along a direction from the first substrate to the first dielectric layer and extend into the first dielectric layer to a partial thickness; and
an isolation ring structure, arranged in the first substrate around the plurality of TSV structures and extending through the first substrate along the direction from the first substrate to the first dielectric layer.

In an exemplary implementation, a plurality of isolation ring structures are arranged.

In an exemplary implementation, the isolation ring structure includes at least one of the following: a first deep trench isolation structure; or
a shallow trench isolation structure and a second deep trench isolation structure on the shallow trench isolation structure.

In an exemplary implementation, the first deep trench isolation structure includes a first deep trench, a first isolation layer on a bottom and a sidewall of the first deep trench, and a first isolation material layer on the first isolation layer and filling the first deep trench.

In an exemplary implementation, a material of the first isolation layer includes at least one of silicon oxide, silicon nitride, or a high-k dielectric material.

In an exemplary implementation, the first isolation material layer includes at least one of polysilicon, copper, or tungsten.

In an exemplary implementation, a material of the shallow trench isolation structure includes a shallow trench and a second isolation material layer in the shallow trench.

In an exemplary implementation, a material of the second isolation material layer includes silicon oxide.

In an exemplary implementation, the second deep trench isolation structure includes a second deep trench, a second isolation layer on a bottom and a sidewall of the second deep trench, and a third isolation material layer on the second isolation layer and filling the second deep trench.

In an exemplary implementation, a material of the second isolation layer includes at least one of silicon oxide, silicon nitride, or a high-k dielectric material.

In an exemplary implementation, the third isolation material layer includes at least one of polysilicon, copper, or tungsten.

In an exemplary implementation, the semiconductor structure further includes
a second wafer, bonded to the first wafer and including a second substrate and a second dielectric layer on the second substrate, where the second dielectric layer faces the first dielectric layer.

In an exemplary implementation, the first wafer further includes:
a first interconnecting structure, arranged in the first substrate and electrically connected to the TSV structure; and
a first bonding and interconnecting layer, arranged in the first substrate above the first interconnecting structure and electrically connected to the first interconnecting structure and the second wafer.

In an exemplary implementation, the second wafer further includes:
a second interconnecting structure, arranged in the second substrate; and
a second bonding and interconnecting layer, arranged in the second substrate above the second interconnecting structure and electrically connected to the second interconnecting structure and the first bonding and interconnecting structure.

In an exemplary implementation, the semiconductor structure further includes:
a passivation layer, arranged on a surface of the first substrate facing away from the first dielectric layer; and
a pad structure, arranged in the passivation layer and electrically connected to the TSV structure.

In an exemplary implementation, a material of the passivation layer includes at least one of silicon oxide, silicon nitride, or a high-k dielectric material.

In another aspect of the present disclosure, a method for forming a semiconductor structure is provided. The method may include:
providing a first wafer, where the first wafer includes a first substrate and a first dielectric layer on the first substrate;
forming an annular isolation ring structure in the first substrate, where the isolation ring structure extends through the first substrate along a direction from the first substrate to the first dielectric layer; and
forming a plurality of TSV structures in an array arrangement in the first substrate, where the TSV structures extend through the first substrate along the direction from the first substrate to the first dielectric layer and extend into the first dielectric layer to a partial thickness, and in the first substrate, the isolation ring structure surrounds a periphery of the plurality of TSV structures in the array arrangement after the plurality of TSV structures in the array arrangement are formed.

In an exemplary implementation, the method for forming a semiconductor structure further includes:
providing a second wafer, where the second wafer includes a second substrate and a second dielectric layer on the second substrate; and
orienting the first dielectric layer toward the second dielectric layer, inverting the first wafer on the second wafer, and bonding the first wafer to the second wafer.

In an exemplary implementation, the isolation ring structure includes a first deep trench isolation structure or a shallow trench isolation structure and a second deep trench isolation structure on the shallow trench isolation structure.

A step of forming the first deep trench isolation structure includes: forming a first deep trench in the first substrate after bonding the first wafer to the second wafer; and filling the first deep trench with a first isolation material layer to form the first deep trench isolation structure.

A step of forming the shallow trench isolation structure and the second deep trench isolation structure on the shallow trench isolation structure includes: forming a shallow trench on a surface of the first substrate facing the first dielectric layer before bonding the first wafer to the second wafer; filling the shallow trench with a second isolation material layer to form the shallow trench isolation structure; forming a second deep trench on the shallow trench isolation structure after bonding the first wafer to the second wafer; and filling the second deep trench with a third isolation material layer to form the second deep trench isolation structure.

Compared with the prior art, the present disclosure has the following advantages:

It may be seen that due to the existence of the isolation ring structure, the TSV structure can be isolated, so that an adverse effect on the first substrate caused by parasitic capacitance generated by a sidewall of the TSV structure can be avoided, and electricity can be prevented from leaking from the sidewall of the TSV structure to the first substrate under a high pressure. Therefore, performance of the formed semiconductor structure can be improved.

### BRIEF DESCRIPTION OF THE DRAWINGS

FIG. 1 is a schematic structural diagram of a semiconductor structure according to a form of the present disclosure.

FIG. 2 is a schematic top view of an isolation structure and a first region according to a form of the present disclosure.

FIG. 3 to FIG. 8 are schematic diagrams of a middle structure formed using steps of a method for forming a semiconductor structure according to a form of the present disclosure.

FIG. 9 is a flowchart of a method for forming a semiconductor structure according to a form of the present disclosure.

### DETAILED DESCRIPTION

An existing semiconductor structure has poor performance. In order to address the problem, a form of the present disclosure provides a semiconductor structure. The semiconductor structure includes: a first wafer, including a first substrate and a first dielectric layer on the first substrate, where a plurality of through-silicon via (TSV) structures in an array arrangement are formed in the first substrate, and the TSV structures extend through the first substrate along a direction from the first substrate to the first dielectric layer and extend into the first dielectric layer to a partial thickness; and an isolation ring structure, arranged in the first substrate around the plurality of TSV structures and extending through the first substrate along the direction from the first substrate to the first dielectric layer.

It may be seen that due to the existence of the isolation ring structure, the TSV structure can be isolated, so that an adverse effect on the first substrate caused by parasitic capacitance generated by a sidewall of the TSV structure can be avoided, and electricity can be prevented from leaking from the sidewall of the TSV structure to the first substrate under a high pressure. Therefore, performance of a formed CMOS image sensor can be improved.

To make the foregoing objectives, features, and advantages of the present disclosure more clearly understood, specific forms of the present disclosure are described in detail below with reference to the accompanying drawings.

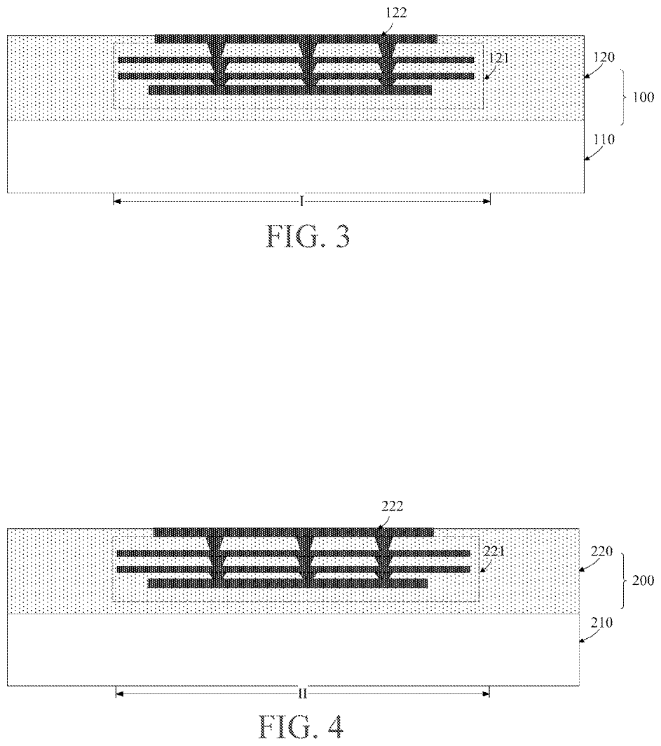

FIG. 1 shows a schematic diagram of a semiconductor structure according to a form of the present disclosure. Referring to FIG. 1, the semiconductor structure includes: a first wafer 100, where the first wafer 100 includes a first substrate 110 and a first dielectric layer 120 on the first substrate 110, and includes a first region I (referring to FIG. 3), a plurality of TSV structures 111 in an array arrangement are formed in the first substrate 110 and the first dielectric layer 120 of the first region I, and the TSV structures 111 extend through the first substrate 110 along a direction from the first substrate 110 to the first dielectric layer 120 and extend into the first dielectric layer 120 to a partial thickness; and an isolation ring structure 112, arranged around the plurality of TSV structures 111 and extending through the first substrate 110 along the direction from the first substrate 110 to the first dielectric layer 120.

In this form, the semiconductor structure is a 3D stacked back side illuminated (BSI) CMOS image sensor. Accordingly, the semiconductor structure includes the first wafer 100.

In this form, the first wafer 100 is a photosensitive wafer. Accordingly, the first wafer 100 has a plurality of image sensor chips. The image sensor chip is configured to receive a light signal and convert the light signal to an electrical signal. The image sensor chip is correspondingly a CMOS image sensor chip.

After the first wafer 100 is bonded to the second wafer, the first wafer 100 and the second wafer are stacked together to form a CMOS image sensor.

In this form, the first wafer 100 includes the first substrate 110.

In this form, the first substrate 110 is a silicon substrate. In other forms, a material of the first substrate may further be other materials such as germanium, silicon germanium, silicon carbide, gallium arsenide, indium gallium, or the like. The first substrate may further be other types of substrates such as a silicon substrate on an insulator or a germanium substrate on the insulator.

In this form, the first wafer 100 further includes the first dielectric layer 120 on the first substrate 110.

The first dielectric layer 120 of the first region I has a first interconnecting structure 121. Accordingly, the first dielectric layer 120 is configured to achieve electrical isolation of the first interconnecting structure formed in the first dielectric layer.

A material of the first dielectric layer 120 may be a low-k dielectric material or an ultra-low-k dielectric material, so that parasitic capacitance of the first interconnecting structure can be effectively reduced, thereby reducing a RC delay of a device. The low-k dielectric material is a dielectric material having a relative dielectric constant greater than or equal to 2.6 and less than or equal to 3.9, and the ultra-low-k dielectric material is a dielectric material having a relative dielectric constant less than 2.6.

In this form, a material of the first dielectric layer 120 is porous carbon-doped silicon oxide (SiOCH). In other forms, the material of the first dielectric layer 120 may further be silanol (SiOH), fluorine-doped silicon oxide (FSG), boron-doped silicon oxide (BSG), phosphorus-doped silicon oxide (PSG), boron and phosphorus doped silicon oxide (BPSG), hydrogen silsesquioxane (HSQ), or methylsilsesquioxane (MSQ).

In this form, the first wafer 100 includes a first region I. A plurality of TSV structures 111 in an array arrangement are formed in the first substrate 110 and the first dielectric layer 120 of the first region I, and the TSV structures 111 extend through the first substrate 110 along a direction from the first substrate 110 to the first dielectric layer 120 and extend into the first dielectric layer 120 to a partial thickness.

The first region I is a part of a chip region of the first wafer 100. A CMOS device is formed in the chip region of the first wafer 100. The CMOS device includes, but is not limited to, a transistor and a photodiode.

The TSV structure 111 is configured to be electrically connected to the CMOS device formed in the chip region of the first wafer 100, the first interconnecting structure in the first dielectric layer 120, and a pad structure in a passivation layer subsequently formed above the first region I. Compared with the conventional wire bonding or a three-dimensional stacking technology using a bump, the TSV structure 111 can increase a number of chips stacked in a three-dimensional direction, reduce an overall dimension, and improve packaging efficiency.

The TSV structure 111 includes a first via (not shown) extending through the first substrate 110 and extending into the first dielectric layer 120 to a partial thickness along the direction from the first substrate 110 to the first dielectric layer 120, and a conductive medium (not shown) filling the first via. In this form, a material of the conductive medium is copper. Copper has low resistivity, a high melting point, and low electromobility of copper atoms, and is adapted to be used as a filling material of the TSV structure.

In addition, the TSV structure 111 further includes an insulation layer and a diffusion barrier layer on a bottom and a sidewall of the first via. A material of the insulation layer is silicon oxide, and the insulation layer is configured to achieve electrical insulation between the conductive medium and the first substrate 110 as well as the first dielectric layer 120. A material of the barrier layer is tantalum or tantalum nitride, and the barrier layer is configured to prevent an atom of the conductive medium from diffusing to the insulation layer and the first substrate 110.

In this form, along the direction from the first substrate 110 to the first dielectric layer 120, the TSV structures 111 extend through the first substrate 110 and extend into the first dielectric layer 120 to a partial thickness, and contact the first interconnecting structure formed in the first dielectric layer 120, so as to realize the electrical connection between the TSV structure and the first interconnecting structure.

A number of the TSV structures 111 may be set according to requirements, which is not limited herein. The isolation ring structure 112 is formed in the first substrate 110 on a periphery of the first region I.

The isolation ring structure 112 is arranged in the first substrate surrounding the periphery of the plurality of TSV structures 111 and extends through the first substrate 110 along the direction from the first substrate 110 to the first dielectric layer 120, so as to realize full electrical isolation of the plurality of TSV structures 111.

Specifically, the arrangement of the isolation ring structure 112 may avoid the adverse effect of parasitic capacitance of the sidewall of the TSV structure 111 on the first substrate 110, and may prevent electricity from leaking from the TSV structure 111 to the first substrate 110 under a high pressure, which accordingly contributes to improving the performance of the formed semiconductor structure.

In this form, the isolation ring structure 112 includes a first deep trench isolation structure. Specifically, the first deep trench isolation structure is arranged in the first substrate 110 on the periphery of the first region I around the plurality of TSV structures 111, and extends through the first substrate 110 along the direction from the first substrate 110 to the first dielectric layer 120.

In this form, the first deep trench isolation structure includes a first deep trench, a first isolation layer on a bottom and a sidewall of the first deep trench, and a first conductive medium on the first isolation layer and filling the first deep trench.

Correspondingly, a step of forming the first deep trench isolation structure includes: forming a first deep trench (not shown) in the first substrate; forming a first isolation layer on a bottom and a sidewall of the first deep trench; and forming, on the first isolation layer, a first isolation material layer filling the first deep trench, so as to form the first deep trench isolation structure.

A step of forming the first deep trench includes: forming a patterned first mask layer (not shown) on a surface of the first substrate 110 facing away from the first dielectric layer 120; etching the first substrate 110 by using the patterned first mask layer as a mask, to form the first deep trench (not shown); and removing the remaining first mask layer after the first deep trench is formed.

A material of the first mask layer is photoresist. Correspondingly, the process of forming the patterned first mask layer includes development and photolithography.

In this form, the process of etching the first substrate 110 by using the patterned first mask layer as the mask is a dry etching process.

In this form, a material of the first isolation layer is silicon oxide. In other forms, the first isolation layer may further be made of other suitable materials, such as a high-k dielectric material.

In this form, the process of forming the first isolation layer is an atomic layer deposition process.

In this form, the material of the first isolation material layer is tungsten. In other forms, the material of the first isolation material layer may further be polysilicon or other metal materials (such as copper).

The step of forming the first isolation material layer includes: forming a first initial isolation material layer covering the first substrate 110 and the first isolation layer and filling the first deep trench; and planarizing the first initial isolation material layer until a surface of the first substrate is exposed, to form the first isolation material layer.

In this form, the process of forming the first isolation material layer is a chemical vapor deposition process. Specifically, the first isolation material layer is formed by high-density plasma (HDP) chemical vapor deposition.

In this form, the process of planarizing the first isolation material layer is a chemical mechanical polishing process.

In other forms, the isolation ring structure may further include a shallow trench isolation structure and a second deep trench isolation structure on the shallow trench isolation structure.

In the form, the shallow trench isolation structure includes a shallow trench and a second isolation material layer filling the shallow trench. In additional forms, the shallow trench may further be selectively filled with a conductive medium, such as copper or tungsten.

In the form, a material of the second isolation material layer is silicon oxide.

In the form, the second deep trench isolation structure includes a second deep trench, a second isolation layer on a bottom and a sidewall of the second deep trench, and a second isolation material layer on the second isolation layer and filling the second deep trench.

For the second deep trench, the second isolation layer, and the second isolation material layer, reference is made to the corresponding content in the first deep trench isolation structure for implementation, and details will not be described herein again.

Correspondingly, a step of forming the shallow trench isolation structure and the second deep trench isolation structure on the shallow trench isolation structure includes: forming a shallow trench on a surface of the first substrate facing the first dielectric layer before bonding the first wafer to the second wafer; filling the shallow trench with a second isolation material layer to form the shallow trench isolation structure; forming a second deep trench in the first substrate above the shallow trench isolation structure after bonding the first wafer to the second wafer; forming a second isolation layer on a bottom and a sidewall of the second deep trench; and forming, on the second isolation layer, a third isolation material layer filling the second deep trench, to form the second deep trench isolation structure.

The step of forming the shallow trench includes: forming a patterned second mask layer (not shown) on the surface of the first substrate 110 facing the first dielectric layer 120; etching the first substrate 110 by using the patterned second mask layer as a mask, to form the shallow trench; and removing the remaining second mask layer after the shallow trench is formed.

In the form, a material of the second mask layer is photoresist. Correspondingly, the process of forming the patterned second mask layer includes development and photolithography.

In the form, the process of etching the first substrate by using the patterned second mask layer as the mask is a dry etching process.

The step of filling the shallow trench with the second isolation material layer includes: forming a second isolation material layer covering the surface of the first substrate facing the first dielectric layer and filling the shallow trench; and planarizing the second isolation material layer until the surface of the first substrate facing the first dielectric layer is exposed.

In the form, the process of forming the second isolation material layer is a chemical vapor deposition process. In the form, the process of planarizing the first isolation material layer is a chemical mechanical polishing process.

For the method for forming the second deep trench isolation structure, reference is made to the method for forming the first deep trench isolation structure for implementation, and details will not be described herein again.

One isolation ring structure 112 is arranged by way of example above. It may be understood that a plurality of isolation ring structures 112 may further be arranged according to an actual requirement, which is not limited herein. When the plurality of isolation ring structures 112 are arranged, each isolation ring structure 112 may be any of the first deep trench isolation structure or the shallow trench isolation structure and the second deep trench isolation structure on the shallow trench isolation structure.

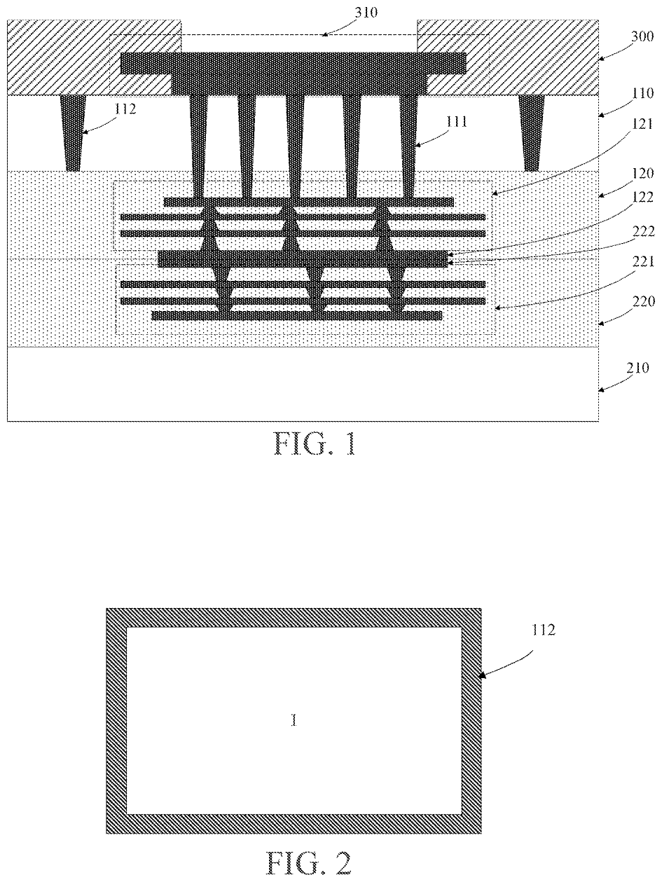

A shape of the isolation ring structure 112 may be the same as or different from a shape of the first region I. As shown in FIG. 2, in this form, the shape of the isolation ring structure 112 is the same as the shape of the first region I, which is a rectangle. In other forms, the isolation ring structure may further be circular, or the like.

A first interconnecting structure 121 and a first bonding and interconnecting layer 122 are formed in the first dielectric layer 120 of the first region I.

The first interconnecting structure 121 is configured to be electrically connected to the TSV structure 111, and is configured to be electrically connected to the first bonding and interconnecting structure in the first dielectric layer 120.

The first interconnecting structure 121 includes a first interconnecting layer structure (not shown) composed of a plurality of metal interconnecting lines and a first interconnecting via structure (not shown) composed of a plurality of first vias used for connecting the metal interconnecting lines.

The first bonding and interconnecting layer 122 is configured to be electrically connected to the second wafer after bonding the first wafer 100 to the second wafer, so as to realize the electrical connection between the first wafer 100 and the second wafer.

In this form, a material of the first bonding and interconnecting layer 122 is copper. In other forms, the material of the first bonding and interconnecting layer may further be other metal materials, such as tungsten, aluminum, and the like.

In this form, the semiconductor structure is a 3D stacked BSI CMOS image sensor. Correspondingly, the semiconductor structure further includes a second wafer 200 bonded to the first wafer 100.

In this form, the second wafer 200 is a signal processing (Digital Signal Processor, DSP) wafer. Specifically, the second wafer 200 has a plurality of signal processing chips. A logic circuit for signal control, reading, and processing is formed in each signal processing chip, and the signal processing chip is configured to process an electrical signal converted from a light signal.

The signal processing chip in the second wafer 200 is arranged opposite to the image sensor chip and the signal processing chip in the first wafer 100, so that the image sensor chip and the signal processing chip are less restricted by each other, and both the image sensor chip and the signal processing chip can easily obtain optimal performance. In this way, packaging performance is improved. In addition, the image sensor chip and the signal processing chip may be combined arbitrarily, so that the semiconductor structure has higher flexibility.

In addition, the image sensor chip and the signal processing chip are arranged on different chips, so that the image sensor chip has a smaller area, thereby reducing design costs of the image sensor chip, and accordingly reducing the packaging costs.

Furthermore, the second wafer 200 may further play a role of supporting the first wafer 100. During grinding of the first wafer 100, the second wafer 200 can improve mechanical strength of the first wafer 100 and reduce a probability of cracking of the first wafer 100, thereby improving reliability of the semiconductor structure.

In this form, the second wafer 200 includes a second substrate 210 and a second dielectric layer 220 on the second substrate 210, and the second dielectric layer 220 faces the first dielectric layer 120.

In this form, a second interconnecting structure 221 and a second bonding and interconnecting layer 222 are formed in the second dielectric layer 220 of the second region II.

For the second substrate 210 and the second dielectric layer 220, reference is made to the description of the first substrate 110 and the first dielectric layer 120, and details will not be described herein again.

In this form, the second wafer 200 includes a second region II. The second region II is arranged opposite to the first region I.

Correspondingly, the second interconnecting structure 221 and the second bonding and interconnecting layer 222 are formed in the second dielectric layer 220 of the second region II.

For the second interconnecting structure 221 and the second bonding and interconnecting layer 222, reference is made to the above content of the first interconnecting structure 121 and the first bonding and interconnecting layer 122 for implementation, and details will not be described herein again.

In this form, the semiconductor structure further includes a passivation layer 300 and a pad structure 310 in the passivation layer 300.

The passivation layer 300 is configured to isolate and protect the pad structure 310.

In this form, the material of the passivation layer 300 is silicon nitride (SiN). In other forms, the material of the passivation layer 300 may further be one or more of silicon nitride or a high-k dielectric material.

The pad structure 310 is configured to be electrically connected to the TSV structure 111 and electrically lead out the formed 3D stacked BSI CMOS image sensor, so that the electrical connection between the 3D stacked BSI CMOS image sensor and the outside and probing of the 3D stacked BSI CMOS image sensor are realized by using the pad structure 310.

In this form, the pad structure 310 includes a pad via (not shown) and a pad interconnecting layer (not shown) on the pad via.

The semiconductor structure in this form of the present disclosure is described by using the 3D stacked BSI CMOS image sensor as an example above. The semiconductor structure may further be other semiconductor structures, which is not limited herein in the present disclosure.

Accordingly, a form of the present disclosure further provides a method for forming a semiconductor structure.

Referring to FIG. 3, a first wafer 100 is provided (901). The first wafer 100 includes a first substrate 110 and a first dielectric layer 120 on the first substrate 110, and the first wafer 100 includes a first region I.

In this form, the first wafer 100 is a photosensitive wafer. Specifically, the first wafer 100 has a plurality of image sensor chips. After the first wafer 100 is bonded to the second wafer subsequently, the first wafer 100 and the second wafer are configured to form a 3D stacked BSI CMOS image sensor. Therefore, the image sensor chip is correspondingly a CMOS image sensor chip.

The first wafer 100 includes a first substrate 110.

In this form, the first substrate 110 is a silicon substrate. In other forms, a material of the first substrate may further be other materials such as germanium, silicon germanium, silicon carbide, gallium arsenide, indium gallium, or the like. The substrate may further be other types of substrates such as a silicon substrate on an insulator or a germanium substrate on the insulator.

In this form, the first wafer 100 further includes a first dielectric layer 120.

A material of the first dielectric layer 120 may be a low-k dielectric material or an ultra-low-k dielectric material, so that parasitic capacitance between the first interconnecting structure can be effectively reduced, thereby reducing a RC delay of a device. The low-k dielectric material is a dielectric material having a relative dielectric constant greater than or equal to 2.6 and less than or equal to 3.9, and the ultra-low-k dielectric material is a dielectric material having a relative dielectric constant less than 2.6.

In this form, a material of the first dielectric layer 120 is porous carbon-doped silicon oxide (SiOCH). In other forms, the material of the first dielectric layer may further be silanol (SiOH), fluorine-doped silicon oxide (FSG), boron-doped silicon oxide (BSG), phosphorus-doped silicon oxide (PSG), boron and phosphorus doped silicon oxide (BPSG), hydrogen silsesquioxane (HSQ), or methylsilsesquioxane (MSQ).

The first wafer 100 includes a first region I, and the first region I is a part of a chip region of the first wafer 100. Various CMOS devices are formed in the chip region of the first wafer 100. Each CMOS device includes, but is not limited to, a transistor and a photodiode.

A first interconnecting structure 121 and a first bonding and interconnecting layer 122 are formed in the first dielectric layer 120 of the first region I.

The first interconnecting structure 121 includes a first interconnecting layer structure (not shown) composed of a plurality of metal interconnecting lines and a first via structure (not shown) composed of a plurality of first vias used for connecting the metal interconnecting lines.

The first bonding and interconnecting layer 122 is configured to be electrically connected to the second wafer after bonding the first wafer 100 to the second wafer, so as to realize the electrical connection between the first wafer 100 and the second wafer.

In this form, a material of the first bonding and interconnecting layer 122 is copper. In other forms, the material of the first bonding and interconnecting layer may further be other metal materials, such as tungsten, aluminum, and the like.

During manufacturing of the first wafer 100, the first interconnecting structure 121 and the first bonding and interconnecting layer 122 are formed in the first dielectric layer 120 of the first region I.

It should be noted that various methods commonly used in the art may be selected as the method for manufacturing the first wafer 100, and details will not be described herein again.

With reference to FIG. 4, in this form, the method for forming a semiconductor structure further includes providing a second wafer 200. The second wafer 200 includes a second substrate 210 and a second dielectric layer 220 on the second substrate 210. The second wafer 200 includes a second region II, and the second region II is arranged opposite to the first region I.

In this form, the second wafer 200 is a signal processing wafer. Specifically, the second wafer 200 has a plurality of signal processing chips. Each signal processing chip is configured to process an electrical signal converted from a light signal.

In this form, a size of the second wafer 200 is the same as a size of the first wafer 100. Correspondingly, the second wafer 200 includes the second region II, and the second region II is at a position corresponding to the first region I.

The second wafer 200 includes a second substrate 210 and a second dielectric layer on the second substrate 210. The second interconnecting structure 221 and the second bonding and interconnecting layer 222 are formed in the second dielectric layer 220 of the second region II.

For the second substrate 210, the second dielectric layer 220, the second interconnecting structure 221, and the second bonding and interconnecting layer 222, reference may be made to the foregoing corresponding description of the first wafer 100, and various methods commonly used in the art may be selected as the method for manufacturing the second wafer 200, and details will not be described herein again.

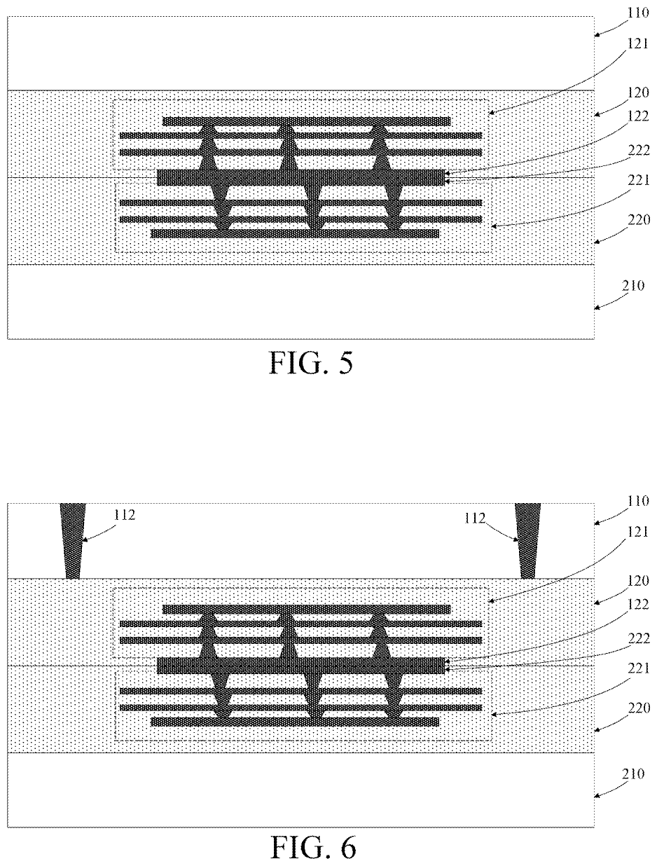

With reference to FIG. 5, in this form, the method for forming a semiconductor structure further includes orienting the first dielectric layer 120 toward the second dielectric layer 210, and bonding the first wafer 100 to the second wafer 200.

The first wafer 100 is first bonded to the second wafer 200, so that the second wafer 200 supports the first wafer 100. In the subsequent process, the second wafer 200 can improve the mechanical strength of the first wafer 100 and reduce the probability of cracking of the first wafer 100, thereby improving reliability of the formed semiconductor structure.

In this form, the second wafer 200 and the first wafer 100 are bonded by using a bonding process. Specifically, the bonding process may be a fusion bonding process. By using the fusion bonding process, the second wafer 200 and the first wafer 100 are bonded by a Si—O bond, thereby improving the bonding force between the second wafer 200 and the first wafer 100.

In this form, after the first wafer 100 is bonded to the second wafer 200, the method further includes grinding a surface of a side of the first substrate 110 facing away from the first dielectric layer 120.

The first substrate 110 is ground to reduce a thickness of the first substrate 110 and reduce an incident optical path, and the difficulty of etching in subsequent formation of a TSV trench and an isolation ring trench can be reduced.

A thickness of the first substrate 110 after being ground may be set according to an actual process requirement. In an example, the thickness of the first substrate 110 after being ground ranges from about 3 μm to 10 μm.

With reference to FIG. 6, an isolation ring structure 112 surrounding the first substrate 110 of the first region I is formed in the first substrate 110, and the isolation ring structure 112 extends through the first substrate 110 along the direction from the first substrate 110 to the first dielectric layer 120 (902).

The isolation ring structure 112 surrounds the first substrate 110 of the first region I, and extends through the first substrate 110 along the direction from the first substrate 110 to the first dielectric layer 120. After the plurality of TSV structures in an array arrangement are subsequently formed in the first substrate 110 and the first dielectric layer 120 of the first region, the isolation ring structure 112 surrounds peripheries of the plurality of TSV structures 111, so as to realize full electrical isolation of the plurality of TSV structures 111.

Specifically, the arrangement of the isolation ring structure 112 may avoid the adverse effect of parasitic capacitance of the sidewall of the TSV structure 111 on the first substrate 110, and may prevent electricity from leaking from the TSV structure 111 to the first substrate 110 under a high pressure, which accordingly contributes to improving the performance of the formed semiconductor structure.

In this form, the isolation ring structure 112 includes a first deep trench isolation structure. Specifically, the first deep trench isolation structure surrounds the first substrate 110 of the first region I in the first substrate 110 and extends through the first substrate 110 along the direction from the first substrate 110 to the first dielectric layer 120.

In this form, the first deep trench isolation structure includes a first deep trench, a first isolation layer on a bottom and a sidewall of the first deep trench, and a first conductive medium on the first isolation layer and filling the first deep trench.

Correspondingly, a step of forming the first deep trench isolation structure includes: forming a first deep trench (not shown) in the first substrate; forming a first isolation layer on a bottom and a sidewall of the first deep trench; and forming, on the first isolation layer, a first isolation material layer filling the first deep trench, so as to form the first deep trench isolation structure.

A step of forming the first deep trench includes: forming a patterned first mask layer (not shown) on a surface of the first substrate 110 facing away from the first dielectric layer 120; etching the first substrate 110 by using the patterned first mask layer as a mask, to form the first deep trench (not shown); and removing the remaining first mask layer after the first deep trench is formed.

A material of the first mask layer is photoresist. Correspondingly, the process of forming the patterned first mask layer includes development and photolithography.

In this form, the process of etching the first substrate 110 by using the patterned first mask layer as the mask is a dry etching process.

In this form, a material of the first isolation layer is silicon oxide. In other forms, the first isolation layer may further be made of other suitable materials, such as a high-k dielectric material.

In this form, the process of forming the first isolation layer is an atomic layer deposition process.

In this form, the material of the first isolation material layer is tungsten. In other forms, the material of the first isolation material layer may further be polysilicon or other metal materials (such as copper).

The step of forming the first isolation material layer includes: forming a first initial isolation material layer covering the first substrate 110 and the first isolation layer and filling the first deep trench; and planarizing the first initial isolation material layer until a surface of the first substrate is exposed, to form the first isolation material layer.

In this form, the process of forming the first isolation material layer is a chemical vapor deposition process. Specifically, the first isolation material layer is formed by high-density plasma (HDP) chemical vapor deposition.

In this form, the process of planarizing the first isolation material layer is a chemical mechanical polishing process.

In other forms, the isolation ring structure may further include a shallow trench isolation structure and a second deep trench isolation structure on the shallow trench isolation structure.

In the form, the shallow trench isolation structure includes a shallow trench and a second isolation material layer filling the shallow trench. In additional forms, the shallow trench may further be selectively filled with a conductive medium, such as copper or tungsten.

In the form, a material of the second isolation material layer is silicon oxide.

In the form, the second deep trench isolation structure includes a second deep trench, a second isolation layer on a bottom and a sidewall of the second deep trench, and a second isolation material layer on the second isolation layer and filling the second deep trench.

For the second deep trench, the second isolation layer, and the second isolation material layer, reference is made to the corresponding content in the first deep trench isolation structure for implementation, and details will not be described herein again.

Correspondingly, a step of forming the shallow trench isolation structure and the second deep trench isolation structure on the shallow trench isolation structure includes: forming a shallow trench on a surface of the first substrate facing the first dielectric layer before bonding the first wafer to the second wafer; filling the shallow trench with a second isolation material layer to form the shallow trench isolation structure; forming a second deep trench in the first substrate above the shallow trench isolation structure after bonding the first wafer to the second wafer; forming a second isolation layer on a bottom and a sidewall of the second deep trench; and forming, on the second isolation layer, a third isolation material layer filling the deep trench, to form the second deep trench isolation structure.

The step of forming the shallow trench includes: forming a patterned second mask layer (not shown) on the surface of the first substrate 110 facing the first dielectric layer 120; etching the first substrate 110 by using the patterned second mask layer as a mask, to form the shallow trench; and removing the remaining second mask layer after the shallow trench is formed.

In the form, a material of the second mask layer is photoresist. Correspondingly, the process of forming the patterned second mask layer includes development and photolithography.

In the form, the process of etching the first substrate by using the patterned second mask layer as the mask is a dry etching process.

The step of filling the shallow trench with the second isolation material layer includes: forming a second isolation material layer covering the surface of the first substrate facing the first dielectric layer and filling the shallow trench; and planarizing the second isolation material layer until the surface of the first substrate facing the first dielectric layer is exposed.

In the form, the process of forming the second isolation material layer is a chemical vapor deposition process.

In the form, the process of planarizing the first isolation material layer is a chemical mechanical polishing process.

For the method for forming the second deep trench isolation structure, reference is made to the method for forming the first deep trench isolation structure for implementation, and details will not be described herein again.

One isolation ring structure 112 is arranged by way of example above. It may be understood that a plurality of isolation ring structures 112 may further be arranged according to an actual requirement. When a plurality of isolation ring structures are arranged, each isolation ring structure can be any of the shallow trench isolation structure or the second deep trench isolation structure on the shallow trench isolation structure.

A shape of the isolation ring 112 may be the same as or different from a shape of the first region I. As shown in FIG. 2, in this form, the shape of the isolation ring structure 112 is the same as the shape of the first region I, which is a rectangle. In other forms, the isolation ring structure may further be circular, or the like.

It should be noted that in the 3D stacked BSI CMOS image sensor, a shallow trench isolation structure and a deep trench isolation structure are formed in the first substrate 110 of the first wafer 100. The isolation ring structure 112 is formed together in the process step of forming the shallow trench isolation structure and the deep trench isolation structure in the first substrate 110, so that no additional mask is required to be added in the process of forming the isolation ring structure 112, which is beneficial to save process costs.

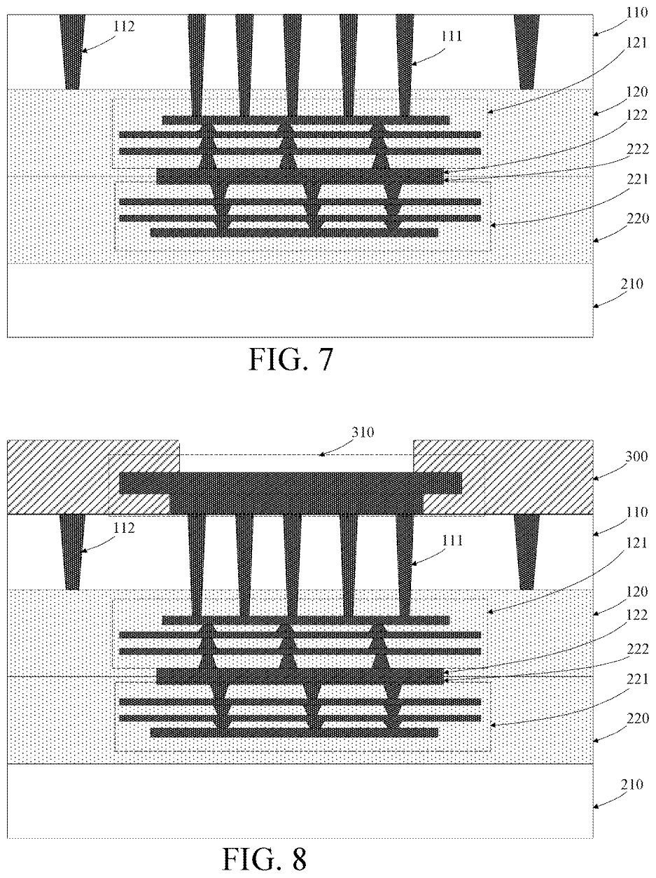

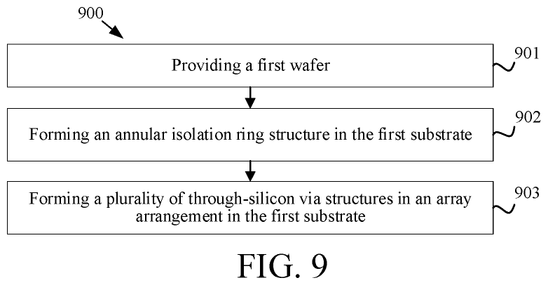

With reference to FIG. 7, a TSV array is formed in the first substrate 110 of the first region I. The TSV array includes a plurality of TSV structures 111 in an array arrangement, and the TSV structures 111 extend through the first substrate 110 and further extends into the first dielectric layer 120 (903).

The TSV structure 111 is configured to be electrically connected to the CMOS device in the first wafer 100, the first interconnecting structure in the first dielectric layer 120, and the pad structure formed in the passivation layer. Compared with the conventional wire bonding or a three-dimensional stacking technology using a bump, the TSV structure 111 can increase a number of chips stacked in a three-dimensional direction, reduce an overall dimension, and improve packaging efficiency.

The TSV structure 111 includes a via extending through the first substrate 110 and extending into the first dielectric layer 120 to a partial thickness, and a conductive medium filling the via. In this form, a material of the conductive medium is copper. Copper has low resistivity, a high melting point, and low electromobility of copper atoms, and is adapted to be used as a filling material of the TSV structure.

In addition, the TSV structure 111 further includes an insulation layer and a diffusion barrier layer on a bottom and a sidewall of the via. A material of the insulation layer is silicon oxide, and the insulation layer is configured to achieve electrical insulation between the conductive medium and the first substrate 110. A material of the barrier layer is tantalum or tantalum nitride, and the barrier layer is configured to prevent an atom of the conductive medium from diffusing to the insulation layer and the first substrate 110.

The TSV structure 111 extends to the first dielectric layer 120 and contacts the first interconnecting structure 121 formed in the first dielectric layer 120, so as to realize the electrical connection between the TSV structure and the first interconnecting structure 121.

In this form, after the first wafer 100 is bonded to the second wafer, the TSV array is formed.

Specifically, the step of forming the TSV structure includes: forming a patterned third mask layer on the surface of the first substrate 110 facing away from the first dielectric layer 120; etching the first substrate 110 and the first dielectric layer 120 to a partial thickness by using the third mask layer as a mask, to form a first via extending through the first substrate 110 and extending into the first dielectric layer 120 to a partial thickness; forming a via material layer covering the first substrate 110 and filling the first via; and planarizing the via material layer until the surface of the first substrate 110 is exposed, to form the TSV structure.

In this form, the third mask layer is a photoresist layer. Correspondingly, the process of forming the patterned third mask layer includes development, photolithography, and the like.

In this form, the process of etching the first substrate 110 and the first dielectric layer 120 to the partial thickness by using the third mask layer as a mask is a dry etching process. Specifically, the dry etching process is a deep plasma dry etching process. Through the deep plasma etching, the first via having a small aperture and a high aspect ratio can be fabricated, an inner wall of the formed first via is relatively smooth, thereby causing little mechanical and physical damage to the first substrate. In other forms, the process for forming the first via may further be laser processing, potassium hydroxide wet etching, photo-electrochemical etching, or the like.

The process of forming the via material layer covering the first substrate 110 and filling the first via includes a chemical vapor deposition process, a physical vapor deposition process, an atomic layer deposition process, or the like. In this form, the via material layer is formed by using a high temperature chemical vapor deposition process.

In this form, the process of planarizing the via material layer is a chemical mechanical polishing process. In other forms, the via material layer may further be planarized by using an etch-back process.

In this form, after the first via is formed, the method further includes forming an insulation layer (not shown) on a bottom and an inner wall of the first via and a barrier layer (not shown) conformally covering the insulation layer. The insulation layer is configured to form electrical insulation between the via material layer and the first substrate 110 as well as the first dielectric layer 120. The barrier layer is configured to prevent a metal atom of the via material layer from diffusing into the insulation layer and the first substrate 110.

In this form, a material of the insulation layer is silicon oxide (SiO₂), and the process for manufacturing silicon oxide is simple and can be directly compatible with a chip integration process. However, the present disclosure does not limit the material of the insulation layer, and the material of the insulation layer may further be silicon nitride (SiN), or the like.

In this form, the method for forming the insulation layer is a chemical vapor deposition process, and the insulation layer deposited by the chemical vapor deposition process has an advantage such as good uniformity. In other forms, the process of forming the insulation layer may further be physical vapor deposition, atomic layer deposition, thermal oxidation, or the like.

In this form, a material of the barrier layer is tantalum (Ta), and tantalum has good barrier and adhesion properties to copper. However, the present disclosure does not limit the material of the barrier layer, and the material of the barrier layer may further be titanium, tantalum nitride, or tantalum silicon nitride.

In this form, the method for forming the barrier layer is the chemical vapor deposition process. The insulation layer deposited by the chemical vapor deposition process has the advantage such as good uniformity. However, the present disclosure does not limit the method for forming the barrier layer, and the method for forming the barrier layer may further be sputtering or the physical vapor deposition process.

In practical application, a number of the TSV structures 111 may be set according to requirements, which is not limited herein.

With reference to FIG. 8, in this form, the method for forming a semiconductor structure further includes forming a passivation layer 300 on the surface of the first substrate 110 facing away from the first dielectric layer 120 and a pad structure 310 arranged in the passivation layer 300 of the first region I.

The passivation layer 300 is configured to isolate and protect the pad structure 310.

In this form, the passivation layer 300 is silicon nitride (SiN). In other forms, a material of the passivation layer 300 may further be one or more of silicon oxide and a high-k dielectric material.

The pad structure 310 is configured to electrically lead out the formed semiconductor structure. Specifically, the pad structure 310 is configured to electrically lead out the 3D stacked CMOS image sensor.

In this form, the pad structure 310 includes a pad via (not shown) and a pad interconnecting layer (not shown) on the pad via.

In this form, the passivation layer includes a first passivation layer, a second passivation layer, and a third passivation layer, and the pad structure 310 includes a pad via (not shown) and a pad interconnecting layer (not shown) on the pad via.

Correspondingly, the step of forming the passivation layer 300 and the pad structure 310 includes: forming a first passivation layer on the surface of the first substrate 110 facing away from the first dielectric layer 120; forming a second via in the first passivation layer of the first region; forming a first pad material layer filling the second via to form a pad via; forming a second passivation layer covering the first passivation layer and the pad via after the pad via is formed; forming a pad interconnecting groove in the second passivation layer of the first region; forming a second pad material layer filling the pad interconnecting groove to form a pad interconnecting layer; forming a third passivation layer covering the second passivation layer and the pad interconnecting layer after the pad interconnecting layer is formed; and forming an opening in the third passivation layer of the first region, where a part of a top surface of the third passivation layer is exposed from the opening.

In this form, after the pad structure is formed, the opening is configured as an electrical lead-out window of the pad structure, so that the electrical connection between the outside and the pad structure 310 is realized through the opening. Therefore, the electrical connection between the 3D stacked BSI CMOS image sensor and the outside is realized, and the probing of the 3D stacked BSI CMOS image sensor can be realized.

The method for forming a semiconductor structure in this form of the present disclosure is described in detail by using the 3D stacked BSI CMOS image sensor as an example above. However, the present disclosure is not limited thereto. The method for forming a semiconductor structure may further be used for forming other semiconductor structures, and the details will not be described herein again.

Although the present disclosure is disclosed above, the present disclosure is not limited thereto. A person skilled in the art can make various changes and modifications without departing from the spirit and the scope of the present disclosure. Therefore, the protection scope of the present disclosure should be subject to the scope defined by the claims.

What is claimed is:

1. A semiconductor structure, comprising:
a first wafer, comprising a first substrate and a first dielectric layer on the first substrate, wherein a plurality of through-silicon via (TSV) structures in an array arrangement are formed in the first substrate, and the TSV structures extend through the first substrate along a direction from the first substrate to the first dielectric layer and extend into a partial thickness of the first dielectric layer; and
an isolation ring structure, arranged in the first substrate around the plurality of TSV structures and extending through the first substrate along the direction from the first substrate to the first dielectric layer.

2. The semiconductor structure according to claim 1, wherein the semiconductor structure comprises a plurality of isolation ring structures.

3. The semiconductor structure according to claim 1, wherein the isolation ring structure comprises:
a first deep trench isolation structure; or
a shallow trench isolation structure and a second deep trench isolation structure on the shallow trench isolation structure.

4. The semiconductor structure according to claim 3, wherein the first deep trench isolation structure comprises a first deep trench, a first isolation layer on a bottom and a sidewall of the first deep trench, and a first isolation material layer on the first isolation layer and filling the first deep trench.

5. The semiconductor structure according to claim 4, wherein a material of the first isolation layer comprises at least one of silicon oxide, silicon nitride, or a high-k dielectric material.

6. The semiconductor structure according to claim 4, wherein the first isolation material layer comprises at least one of polysilicon, copper, or tungsten.

7. The semiconductor structure according to claim 3, wherein a material of the shallow trench isolation structure comprises a shallow trench and a second isolation material layer in the shallow trench.

8. The semiconductor structure according to claim 7, wherein a material of the second isolation material layer comprises silicon oxide.

9. The semiconductor structure according to claim 3, wherein the second deep trench isolation structure comprises a second deep trench, a second isolation layer on a bottom and a sidewall of the second deep trench, and a third isolation material layer on the second isolation layer and filling the second deep trench.

10. The semiconductor structure according to claim 9, wherein a material of the second isolation layer comprises at least one of silicon oxide, silicon nitride, or a high-k dielectric material.

11. The semiconductor structure according to claim 9, wherein the third isolation material layer comprises at least one of polysilicon, copper, or tungsten.

12. The semiconductor structure according to claim 1, further comprising:
a second wafer, bonded to the first wafer and comprising a second substrate and a second dielectric layer on the second substrate, wherein the second dielectric layer faces the first dielectric layer.

13. The semiconductor structure according to claim 12, wherein the first wafer further comprises:
a first interconnecting structure, arranged in the first substrate and electrically connected to the TSV structure; and
a first bonding and interconnecting layer, arranged in the first substrate above the first interconnecting structure and electrically connected to the first interconnecting structure and the second wafer.

14. The semiconductor structure according to claim 13, wherein the second wafer further comprises:
a second interconnecting structure, arranged in the second substrate; and
a second bonding and interconnecting layer, arranged in the second substrate above the second interconnecting structure and electrically connected to the second interconnecting structure and the first bonding and interconnecting layer.

15. The semiconductor structure according to claim 1, further comprising:
a passivation layer, arranged on a surface of the first substrate facing away from the first dielectric layer; and
a pad structure, arranged in the passivation layer and electrically connected to the TSV structure.

16. The semiconductor structure according to claim 15, wherein a material of the passivation layer comprises at least one of silicon oxide, silicon nitride, or a high-k dielectric material.

17. A method for forming a semiconductor structure, comprising:
providing a first wafer, wherein the first wafer comprises a first substrate and a first dielectric layer on the first substrate;
forming an annular isolation ring structure in the first substrate, wherein the annular isolation ring structure extends through the first substrate along a direction from the first substrate to the first dielectric layer; and
forming a plurality of through-silicon via (TSV) structures in an array arrangement in the first substrate, wherein the TSV structures extend through the first substrate along the direction from the first substrate to the first dielectric layer, and extend into a partial thickness of the first dielectric layer, and in the first substrate, the annular isolation ring structure surrounds a periphery of the plurality of TSV structures in the array arrangement after the plurality of TSV structures in the array arrangement are formed.

18. The method for forming the semiconductor structure according to claim 17, further comprising:
providing a second wafer, wherein the second wafer comprises a second substrate and a second dielectric layer on the second substrate; and
orienting the first dielectric layer toward the second dielectric layer, inverting the first wafer on the second wafer, and bonding the first wafer to the second wafer.

19. The method for forming the semiconductor structure according to claim 18, the annular isolation ring structure comprises a first deep trench isolation structure, and the forming the annular isolation ring structure comprises:
forming a first deep trench in the first substrate after bonding the first wafer to the second wafer; and
filling the first deep trench with a first isolation material layer to form the first deep trench isolation structure.

20. The method for forming the semiconductor structure according to claim 18, wherein the annular isolation ring structure comprises a shallow trench isolation structure and a second deep trench isolation structure on the shallow trench isolation structure, and forming the annular isolation ring structure comprises:
forming a shallow trench on a surface of the first substrate facing the first dielectric layer before bonding the first wafer to the second wafer;
filling the shallow trench with a second isolation material layer to form the shallow trench isolation structure;
forming a second deep trench on the shallow trench isolation structure after bonding the first wafer to the second wafer; and
filling the second deep trench with a third isolation material layer to form the second deep trench isolation structure.
